(19) United States
(12) Patent Application Publication
(10) Pub. No.: US 2019/0181015 A1
(43) Pub. Date: Jun. 13, 2019

(54) Substrate Processing Method and Substrate Processing Apparatus

(71) Applicant: TOKYO ELECTRON LIMITED, Tokyo (JP)

(72) Inventors: Tomoaki OGIWARA, Nirasaki City (JP); Hiroyuki TAKAHASHI, Tokyo (JP); Takuya ABE, Nirasaki City (JP); Masahiko TOMITA, Nirasaki City (JP); Shinya IWASHITA, Nirasaki City (JP)

(21) Appl. No.: 16/275,674

(22) Filed: Feb. 14, 2019

Related U.S. Application Data
(62) Division of application No. 15/480,707, filed on Apr. 6, 2017.

(30) Foreign Application Priority Data
Apr. 8, 2016 (JP) 2016-078421

(51) Int. Cl. H01L 21/311; H01L 21/3105; H01L 21/67

(52) U.S. Cl. CPC H01L 21/31116; H01L 21/67069; H01L 21/3105

(57) ABSTRACT

A substrate processing method for removing an oxide film formed on the surface of a substrate includes modifying the oxide film into a reaction product by supplying a halogen element-containing gas and an alkaline gas onto the substrate accommodated in the interior of a processing chamber, and sublimating the reaction product by stopping the supply of the halogen element-containing gas into the processing chamber for removal from the substrate, wherein an internal pressure of the processing chamber in the sublimating is set to be higher than an internal pressure of the processing chamber in the modifying by supplying an inert gas into the processing chamber.

### CROSS-REFERENCE TO RELATED APPLICATION

This application claims the benefit of Japanese Patent Application No. 2016-078421, filed on Apr. 8, 2016, in the Japan Patent Office, the disclosure of which is incorporated herein in its entirety by reference.

### TECHNICAL FIELD

The present disclosure relates to a substrate processing method and a substrate processing apparatus. More particularly, the present disclosure further relates to a substrate processing method and a substrate processing apparatus for removing an oxide film.

### BACKGROUND

In a manufacturing method of an electronic device by using a silicon wafer (hereinafter, referred to as a “wafer”), for example, a film forming process for forming a conductive film or an insulating film on the surface of the wafer, a lithography process for forming a photoresist layer in a predetermined pattern on the formed conductive film or insulating film, an etching process for shaping the conductive film into a gate electrode or for forming a wiring groove or a contact hole in the insulating film by means of plasma generated from a process gas by using the photoresist layer as a mask, and the like are repeatedly performed.

As an example, in a certain manufacturing method of an electronic device, after forming a groove in a predetermined pattern in the polysilicon film that is formed on the surface of the wafer, a silicon oxide film is formed as an oxide film to fill the groove. Then, the silicon oxide film is removed to be a predetermined thickness by etching or the like.

At this time, as a method for removing the silicon oxide film, there has been known a substrate processing method, which performs a COR (Chemical Oxide Removal) process and a PHT (Post Heat Treatment) process with respect to the wafer. The COR process is a process of chemically reacting the silicon oxide film with gas molecules to thereby produce a reaction product. The PHT process is a process of heating the wafer with the COR process performed to sublimate the reaction product that has been produced on the wafer through the chemical reaction of the COR process, for removal from the wafer.

As a substrate processing apparatus for performing the substrate processing method including the COR process and the PHT process, there has been known a substrate process apparatus having a chemical reaction chamber (COR processing chamber) and a heat treatment chamber (PHT processing chamber) connected to the chemical reaction chamber. In addition, another substrate processing apparatus configured to perform the COR process with respect to the wafer at a low temperature, and then perform the PHT process by heating the wafer to a predetermined temperature in the same processing chamber.

However, since the sublimated product stagnates in the vicinity of the wafer in the PHT process, a case of hindering the sublimation of the new reaction product from the wafer may occur. As a result, time is required to perform the PHT process, so that it is difficult to improve the throughput of the oxide film removal.

### SUMMARY

The present disclosure provides a substrate processing method and a substrate processing apparatus capable of improving the throughput of the oxide film removal.

According to one embodiment of the present disclosure, there is provided a substrate processing method for removing an oxide film formed on the surface of a substrate. The method includes modifying the oxide film into a reaction product by supplying a halogen element-containing gas and an alkaline gas onto the substrate accommodated in the interior of a processing chamber, and sublimating the reaction product by stopping the supply of the halogen element-containing gas into the processing chamber for removal from the substrate. An internal pressure of the processing chamber in the sublimating is set to be higher than an internal pressure of the processing chamber in the modifying by supplying an inert gas into the processing chamber.

According to another embodiment of the present disclosure, there is provided a substrate processing apparatus including a processing chamber configured to accommodate a substrate, and a gas supply unit configured to selectively supply a halogen element-containing gas, an alkaline gas, or an inert gas into the processing chamber. The gas supply unit is configured to perform modifying an oxide film formed on the substrate accommodated in the processing chamber into a reaction product by supplying the halogen element-containing gas and the alkaline gas into the processing chamber and sublimating the reaction product for removal from the substrate by stopping the supply of the halogen element-containing gas into the processing chamber. The gas supply unit is configured to supply an inert gas into the processing chamber to set an internal pressure of the processing chamber in the sublimating to be higher than an internal pressure of the processing chamber in the modifying.

### BRIEF DESCRIPTION OF THE DRAWINGS

The accompanying drawings, which are incorporated in, and constitute a part of, the specification, illustrate embodiments of the present disclosure, and together with the general description given above and the detailed description of the embodiments given below, serve to explain the principles of the present disclosure.

FIG. 1 is a plan view schematically showing the configuration of a substrate processing system that adopts a substrate processing apparatus, according to an embodiment of the present disclosure.

FIG. 2 is a cross-sectional view schematically showing the configuration of an etching device in FIG. 1.

FIGS. 3A to 3J are process diagrams showing an oxide film removal process as a substrate processing method according to an embodiment of the present disclosure.

FIG. 4 is a cross-sectional view for explaining stagnation of sublimation of the reaction product from a wafer.

FIGS. 5A and 5B are process diagrams for explaining a method for removing a sublimation gas in a PHT process of the oxide film removal process in FIG. 3.

FIG. 6 is a graph showing an etching amount in the oxide film removal process of FIG. 3 when varying a supply amount of an inert gas in a PHT process.

FIGS. 7A and 7B are cross-sectional views schematically showing configuration of a modified example of the etching device in FIG. 2, wherein FIG. 7A shows a first modified example and FIG. 7B shows a second modified example.

FIGS. 8A to 8D are timing charts showing a supply start or supply stop of various gases in the COR operation and the PHT operation of the oxide film removal process in FIG. 3.

### DETAILED DESCRIPTION

Hereinafter, an embodiment of the present disclosure will be described in detail with reference to the drawings.

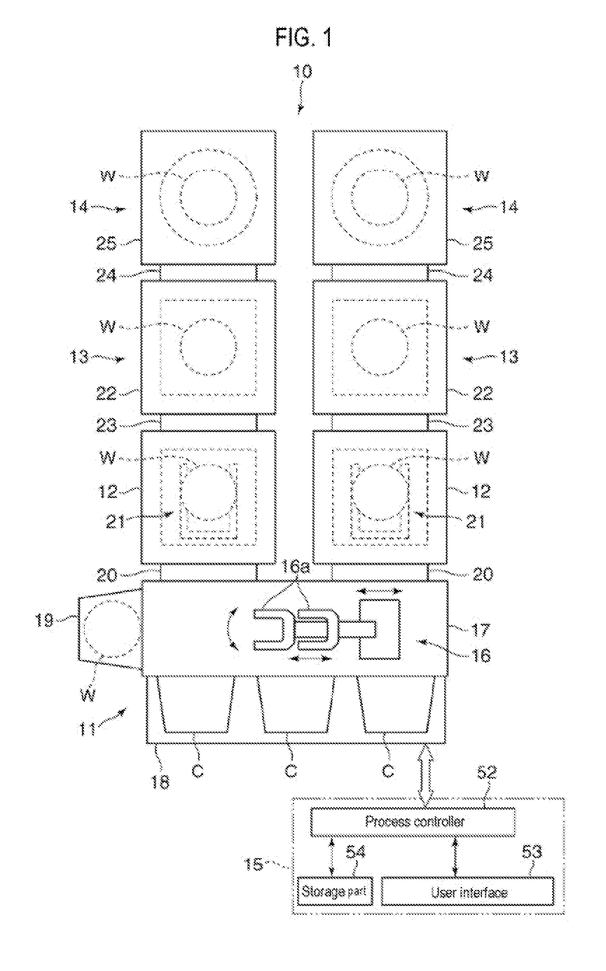

FIG. 1 is a plan view schematically showing the configuration of a substrate processing system that adopts a substrate processing apparatus, according to an embodiment of the present disclosure. In FIG. 1, some elements are illustrated as if they are transparent in order to facilitate the understanding of the present disclosure.

In FIG. 1, the substrate processing system 10 includes a loading/unloading part 11 configured to load/unload a semiconductor wafer (hereinafter, simply referred to as a “wafer”), which is an substrate to be processed substrate, two load lock chambers 12 installed adjacent to the loading/unloading part 11, heat treatment devices 13 installed adjacent to the load lock chambers 12, respectively, and configured to perform heat treatment with respect to the wafer W, etching devices 14 installed adjacent to the heat treatment devices 13, respectively, to perform an oxide film removal process including a COR process and a PHT process with respect to the wafer W, and a control unit 15.

The loading/unloading part 11 has a loader module chamber 17 in which a wafer transfer mechanism 16 for transferring the wafer W is installed. The wafer transfer mechanism 16 has two transfer arms 16a and 16b for holding the wafer W in a substantially horizontal position. A load port 18 is installed in the side portion of the loader module chamber 17 in the longitudinal direction thereof, and, for example, three carriers C capable of receiving a plurality of wafers may be loaded and connected in the load port 18. In addition, an orienter 19, which rotates the wafer to optically measure an eccentric amount of the wafer W, and perform position alignment, is installed adjacent to the loader module chamber 17.

In the loading/unloading unit 11, the wafer W is held by the transfer arms 16a and 16b and is straightly moved on a substantially horizontal plane and elevated by the wafer transfer mechanism 16 to be transferred to a desired position. In addition, the transfer arms 16a and 16b move forward or backward with respect to the carrier C on the load port 18, the orienter 19, and the load lock chamber 12, respectively, to load/unload the wafer W therebetween.

Each load lock chamber 12 is connected to the loader module chamber 17 with a gate valve 20 interposed therebetween. A wafer transfer mechanism 21 for transferring the wafer W is installed in each load lock chamber 12. Further, the load lock chamber 12 is configured to be vacuumized to a predetermined vacuum degree.

The wafer transfer mechanism 21 is provided with an articulated arm structure that has a peak for holding the wafer W in a substantially horizontal position. The peak is positioned inside the load lock chamber 12 during a state of retracting the articulated arm structure, the peak reaches the heat treatment device 13 by expanding the articulated arm structure, and the peak reaches the etching device 14 by further expanding the articulated arm structure. According to this, the wafer transfer mechanism 21 transfers the wafer W between the load lock chamber 12, the heat treatment device 13, and the etching device 14.

The heat treatment device 13 has a chamber 22 that can be vacuumized A mounting table (not shown) for mounting the wafer W thereon is installed in the chamber 22, and a heater (not shown) is embedded in the mounting table. In the heat treatment device 13, the wafer W on which the COR process and PHT process have been repeatedly performed in the etching device 14 is mounted on the mounting table and heated by the heater so that residue, existing on the wafer W after the oxide film removal process, are evaporated to be removed.

A loading/unloading port (not shown) is formed on the side of the chamber 22 facing the load lock chamber 12 for transferring the wafer W to or from the load lock chamber 12, and the loading/unloading port is opened or closed by a gate valve 23. In addition, another loading/unloading port (not shown) is formed on the side of the chamber 22 facing the etching device 14 for transferring the wafer W to or from the etching device 14, and the loading/unloading port is opened or closed by a gate valve 24.

A gas supply path (not shown) is connected to the upper portion of the side wall of the chamber 22, and the gas supply path is connected to a gas supply part (not shown). In addition, an exhaust path (not shown) is connected to the bottom wall of the chamber 22, and the exhaust path is connected to a vacuum pump (not shown). Furthermore, a flow rate control valve is installed in the gas supply path from the gas supply part to the chamber 22, and a pressure control valve is installed in the exhaust path, so that a heat treatment can be performed on the wafer W while maintaining the interior of the chamber 22 to have a predetermined pressure by controlling the valves.

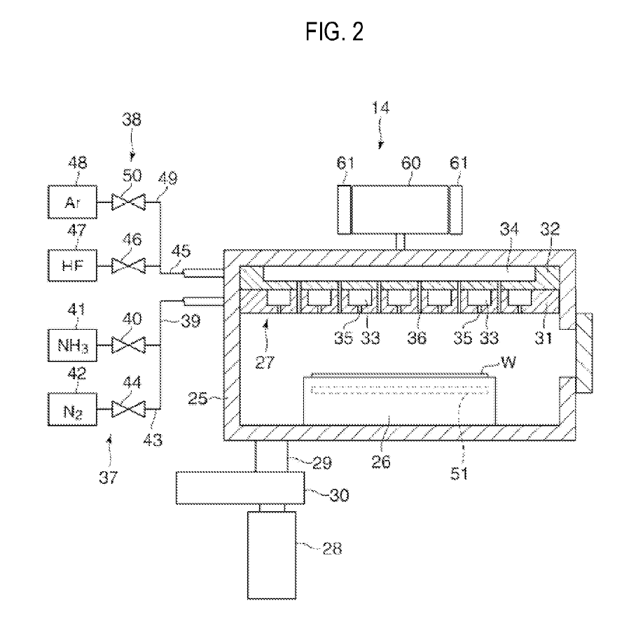

FIG. 2 is a cross-sectional view schematically showing the configuration of the etching device in FIG. 1.

In FIG. 2, the etching device 14 includes a chamber 25 that is a processing chamber, a mounting table 26 that is disposed in the chamber 25, and a shower head 27 that is disposed to face the mounting table 26 in the upper portion of the chamber 25. In addition, the etching device 14 includes a TMP (Turbo Molecular Pump) 28 and an APC (Adaptive pressure control) valve 30, which is disposed between exhaust ducts extending from the TMP 28 and the chamber 25 as a variable valve for controlling the internal pressure of the chamber 25, as an exhaust unit for exhausting gas or the like inside the chamber 25.

The shower head 27 has a double-layer structure comprised of a lower portion 31 and an upper portion 32, wherein the lower portion 31 and the upper portion 32 have a lower buffer chamber 33 and an upper buffer chamber 34, respectively. The lower buffer chamber 33 and the upper buffer chamber 34 communicate with the interior of the chamber 25 through gas vent holes 35 and 36, respectively. That is, the shower head 27 is configured with two plate bodies (the lower portion 31 and the upper portion 32) that are stacked in a layered shape having internal passages for the gases that are supplied from the lower buffer chamber 33 and the upper buffer chamber 34, respectively, to the interior of the chamber 25.

The chamber 25 is connected to an ammonia (NH₃) gas supply system 37 and a hydrogen fluoride (HF) gas supply system 38. The ammonia gas supply system 37 includes an ammonia gas supply pipe 39 communicating with the lower buffer chamber 33 of the lower portion 31, an ammonia gas valve 40 disposed on the ammonia gas supply pipe 39, and an ammonia gas supply part 41 connected to the ammonia gas supply pipe 39. The ammonia gas supply part 41 is configured to supply an ammonia gas to the lower buffer chamber 33 through the ammonia gas supply pipe 39 while adjusting a flow rate of the supplied ammonia gas. The ammonia gas valve 40 is configured to allow the ammonia gas supply pipe 39 to be open or closed.

In addition, the ammonia gas supply system 37 includes a nitrogen (N₂) gas supply part 42, a nitrogen gas supply pipe 43 connected to the nitrogen gas supply part 42, and a nitrogen gas valve 44 disposed on the nitrogen gas supply pipe 43. The nitrogen gas supply pipe 43 is connected to the ammonia gas supply pipe 39 between the lower buffer chamber 33 and the ammonia gas valve 40. The nitrogen gas supply part 42 is configured to supply a nitrogen gas to the lower buffer chamber 33 through the nitrogen gas supply pipe 43 and the ammonia gas supply pipe 39. Further, the nitrogen gas supply part 42 is configured to control a flow rate of the nitrogen gas to be supplied. The nitrogen gas valve 44 is configured to allow the nitrogen gas supply pipe 43 to be open or closed.

In the etching device 14, the type of gas to be supplied to the lower buffer chamber 33 and to be further supplied to the interior of the chamber 25 is selectively switched by switching the opening and closing of the ammonia gas valve 40 and the nitrogen gas valve 44.

The hydrogen fluoride gas supply system 38 includes a hydrogen fluoride gas supply pipe 45 communicating with the upper buffer chamber 34 of the upper portion 32, a hydrogen fluoride gas valve 46 disposed on the hydrogen fluoride gas supply pipe 45, and a hydrogen fluoride gas supply part 47 connected to the hydrogen fluoride gas supply pipe 45. The hydrogen fluoride gas supply part 47 is configured to supply a hydrogen fluoride gas to the upper buffer chamber 34 through the hydrogen fluoride gas supply pipe 45. In addition, the hydrogen fluoride gas supply part 47 is configured to control a flow rate of the hydrogen fluoride gas to be supplied. The hydrogen fluoride gas valve 46 is configured to allow the hydrogen fluoride gas supply pipe 45 to be open or closed. A heater (not shown) is embedded in the upper portion 32 of the shower head 27 to heat the hydrogen fluoride gas inside the upper buffer chamber 34.

In addition, the hydrogen fluoride gas supply system 38 includes, an argon (Ar) gas supply part 48, an argon gas supply pipe 49 connected to the argon gas supply part 48, and an argon gas valve 50 disposed on the argon gas supply pipe 49. The argon gas supply pipe 49 is connected to the hydrogen fluoride gas supply pipe 45 between the upper buffer chamber 34 and the hydrogen fluoride gas valve 46. The argon gas supply part 48 is configured to supply an argon gas to the upper buffer chamber 34 through the argon gas supply pipe 49 and the hydrogen fluoride gas supply pipe 45. Further, the argon gas supply part 48 is configured to control a flow rate of the argon gas to be supplied. The argon gas valve 50 is configured to allow the argon gas supply pipe 49 to be open or closed.

In the etching device 14, the flow rate ratios of the ammonia gas and the hydrogen fluoride gas supplied from the shower head 27 to the interior of the chamber 25 is controlled by cooperation of the ammonia gas supply part 41 of the ammonia gas supply system 37 and the hydrogen fluoride gas supply part 47 of the hydrogen fluoride gas supply system 38. Furthermore, as described above, the etching device 14 is designed such that the ammonia gas and the hydrogen fluoride gas are initially mixed in the interior of the chamber 25 (post-mix design). According to this, it is possible to prevent the ammonia gas and the hydrogen fluoride gas from being mixed and from reacting with each other prior to being introduced into the chamber 25. In addition, a heater (not shown) is embedded in the side wall of the chamber 25 in the etching device 14, so that a decrease of the internal ambient temperature of the chamber 25 can be prevented, and further, the reproducibility of the oxide film removal process can be improved. Also, it is possible to limit reaction products or by-products, which are produced inside the chamber 25 during the oxide film removal process, from being attached onto the inner surface of the side wall thereof by controlling the temperature of the side wall.

The mounting table 26 is fixed to the bottom of the chamber 25. A temperature controller 51 is installed in the mounting table 26 to adjust the temperature of the mounting table 26. For example, the temperature controller 51 is provided with a pipe line through which a temperature control medium, such as water, circulates, and performs a heat-exchange with the temperature control medium flowing through the conduit. Therefore, the temperature of the mounting table 26 is controlled and the temperature of the wafer W on the mounting table 26 is controlled.

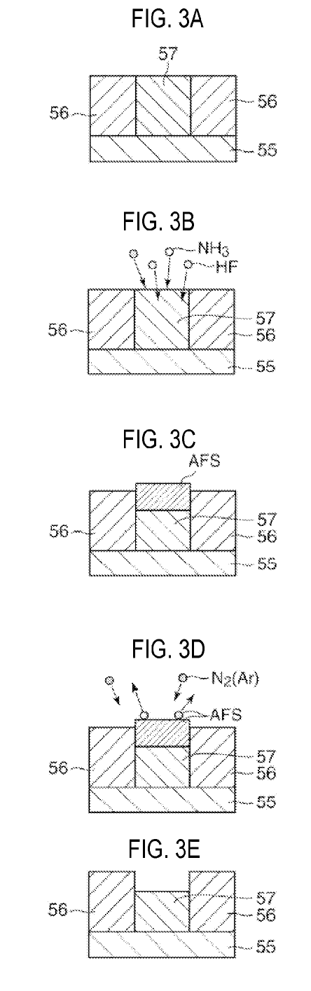

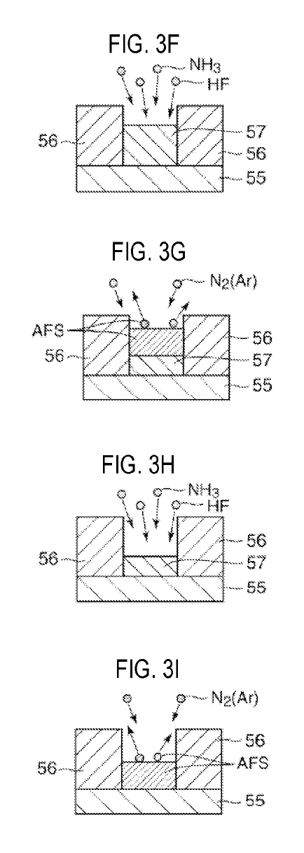

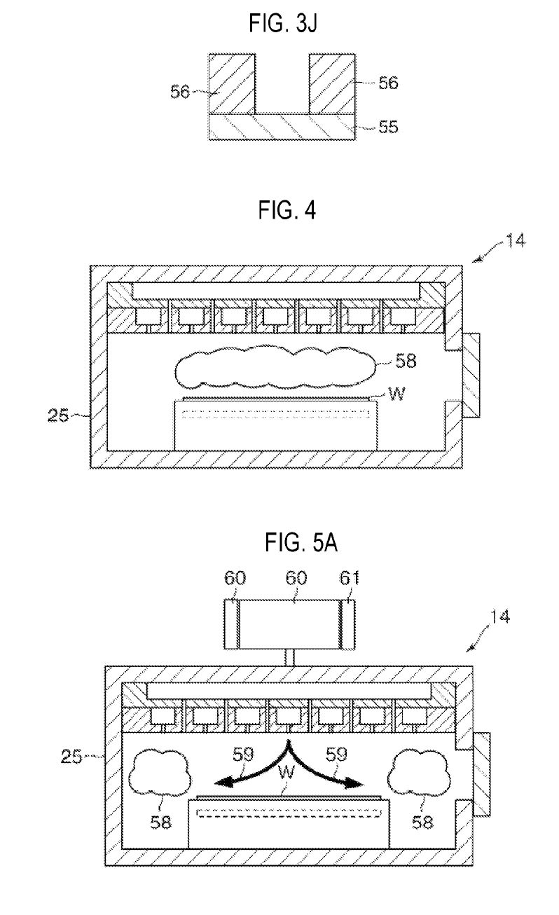

The mounting table 26 includes lift pins (not shown) for lifting the wafer W on the upper surface of the mounting table 26 so as to perform sending/receiving the wafer W to/from the wafer transfer mechanism 21. In addition, the details of the oxide film removal process that is performed in the etching device 14 will be described later with reference to FIG. 3.

Referring back to FIG. 1, the control unit 15 includes a process controller 52 having a microprocessor (computer) for controlling respective elements of the substrate processing system 10. The process controller 52 is connected to a user interface 53, which has a keyboard for performing an input manipulation of commands to manage the substrate processing system 10, a display for visually displaying an operating state of the substrate processing system 10 or the like. In addition, a storage part 54 is connected to the process controller 52. The storage part 54 stores a control program for implementing various processes in the substrate processing system 10, for example, supply of process gases used for the oxide film removal process performed in the etching device 14, exhaust of an interior of the chamber 25 or the like, by means of the control of the process controller 52, a process recipe that is a control program for implementing predetermined processes in the respective elements of the substrate processing system 10 according to a process condition, and various databases. The control unit 15 retrieves the process recipe or the like from the storage part 54, and executes the same in the process controller 52 to thereby perform a desired process.

In the substrate processing system 10 described above, a sheet of wafer W is transferred from the carrier C of the loading/unloading unit 11 into the load lock chamber 12 by means of one of the transfer arms 16a and 16b of the wafer transfer mechanism 16 while the gate valve 20 is opened, and then transferred to the peak of the wafer transfer mechanism 21 in the load lock chamber 12. Thereafter, the gate valve 20 is closed and the load lock chamber 12 is vacuum-exhausted. Subsequently, the gate valve 24 is opened and the peak of the wafer transfer mechanism 21 expands to the etching device 14 so that the wafer W is transferred into the etching device 14.

Next, the peak of the wafer transfer mechanism 21 retracts to the load lock chamber 12, and the gate valve 24 is closed. Then, an oxide film removal process is performed on the wafer W in the etching device 14 as described later. The gate valves 23 and 24 are opened after the oxide film removal process is finished, and the wafer W with the oxide film removal performed is transferred to the heat treatment device 13 by the peak of the wafer transfer mechanism 21 and then mounted on the mounting table installed in the heat treatment device 13. Next, the wafer W on the mounting table is heated by the heater to evaporate residues of the wafer W for removal while introducing an inert gas or the like into the chamber 22.

Subsequently, the gate valve 23 is opened after the residue removal is completed in the heat treatment device 13, and the wafer W on the mounting table of heat treatment device 13 is returned to (stored in) the load lock chamber 12 by the peak of the wafer transfer mechanism 21. Then, the wafer W is returned back to the carrier C by one of the transfer arms 16a and 16b of the wafer transfer mechanism 16. As a result, the process for one sheet of wafer W is completed.

Further, the heat treatment device 13 is optional in the substrate processing system 10. In the case where the heat treatment device 13 is not installed, the wafer W is returned to (stored in) the load lock chamber 12 by the peak of the wafer transfer mechanism 21 after the completion of the oxide film removal process, and is then returned back to the carrier C by one of the transfer arms 16a and 16b of the wafer transfer mechanism 16.

Now, an oxide film removal process performed in the etching device 14 will be described. FIGS. 3A to 3J are process diagrams illustrating an oxide film removal process as the substrate processing method, according to an embodiment of the present disclosure. FIGS. 3A to 3J show respective steps of the oxide film removal process through the enlarged cross-sectional views in the vicinity of the surface of the wafer W. In addition, as illustrated in FIG. 3A, the wafer W has a structure in which a groove is formed in a predetermined pattern on a polysilicon film 56 formed on the surface of a silicon (Si) layer 55 as a substrate, and a silicon oxide (SiO₂) film 57 is formed in the groove. Although a process of completely removing the silicon oxide film 57 from the wafer W is described, the present disclosure may also be applied to a process of partially removing the silicon oxide film 57. In addition, the wafer W is generally manufactured through processes of forming a polysilicon film 56 on the surface of the silicon layer 55, forming a resist film in a predetermined pattern on the polysilicon film 56, forming a groove by etching the polysilicon film 56 using the resist film as an etching mask, removing the resist film, forming a silicon oxide film 57, and performing CMP (Chemical Mechanical Polishing) with respect to the surface. Therefore, as illustrated in FIG. 3A, the silicon oxide film 57 has the same height as the polysilicon film 56 prior to performing the oxide film removal process. The groove in which the silicon oxide film 57 is formed is, for example, an element isolation region in the memory device.

First, when the wafer W is mounted on the mounting table 26 and the chamber 25 is sealed, a nitrogen gas and an argon gas are supplied from the nitrogen gas supply part 42 and the argon gas supply part 48 into the chamber 25, for example, at a flow rate of 150 sccm and for example, at a flow rate of 300 sccm, respectively. In addition, with the operation of the TMP 28, the internal pressure of the chamber 25 is decreased to a predetermined degree of vacuum (for example, 2000 mTorr (=266.63 Pa)), which is lower than atmospheric pressure. Furthermore, the temperature of the wafer W is maintained at a constant temperature (for example, 120 degrees C.) in the range of 80 degrees C. to 120 degrees C. by means of the temperature controller 51. In addition, the temperature of the wafer W is kept at the constant temperature on the mounting table 26 until the oxide film removal process is completed.

Next, the wafer W is subjected to a reaction process (hereinafter, referred to as a “COR process”) in which a portion of the surface side of the silicon oxide film 57 reacts with an ammonia gas and a hydrogen fluoride gas to produce a reaction product. In the COR process, first, an ammonia gas is supplied into the chamber 25 from the ammonia gas supply part 41. At this time, the flow rate of ammonia gas is, for example, 300 sccm. The argon gas and the nitrogen gas are supplied to the interior of the chamber 25, for example, at a flow rate of 150 sccm, and, for example, at a flow rate of 300 sccm, respectively. In addition, the flow rates of the nitrogen and argon gases may not be limited to the embodiment above, and the supply of one of the nitrogen gas and the argon gas may be stopped. At this time, the internal pressure of the chamber 25 is maintained, for example, at 2000 mTorr by the operation of the TMP 28.

Then, a hydrogen fluoride gas is supplied into the chamber 25 from the hydrogen fluoride gas supply part 47, for example, at a flow rate of 450 sccm while continuously supplying the ammonia gas into the chamber 25, for example, at a flow rate of 300 sccm. For example, the ammonia gas and the hydrogen fluoride gas are supplied for three seconds. At this time, the internal pressure of the chamber 25 is also maintained, for example, at 2000 mTorr by the operation of the TMP 28. Here, since the ammonia gas has been previously supplied into the chamber 25, an internal atmosphere of the chamber 25 becomes a mixed gas including the hydrogen fluoride gas and the ammonia gas by supplying the hydrogen fluoride gas thereto. Thus, the silicon oxide film 57 is exposed to the mixed gas to thereby produce reaction products, such as ammonium hexa-fluorosilicate ((NH₄)₂SiF₆) (hereinafter, referred to as “AFS”), water or the like, according to the following reaction formula.

SiO₂+6HF+2NH₃→(NH₄)₂SiF₆+2H₂O↑

FIG. 3B schematically illustrates the COR process in which the hydrogen fluoride gas and the ammonia gas modify the silicon oxide film 57 according to the above reaction formula, and FIG. 3C schematically illustrates a state in which the AFS, which is a main reaction product, is formed on the silicon oxide film 57. In addition, water, which is one of the reaction products, is evaporated.

Next, the wafer W is subjected to a sublimation process (hereinafter, referred to as a “PHT process”) for removing the reaction products (mainly, the AFS) that are produced in the COR process from the wafer W by sublimating the same in the etching device 14. In the PHT process, an argon gas and/or a nitrogen gas are supplied into the chamber 25 while stopping the supply of the hydrogen fluoride gas and ammonia gas. In addition, the temperature of the wafer W is maintained to be the same as that in the COR process (for example, 120 degrees C.) in the range of 80 degrees C. to 120 degrees C. by the temperature controller 51. FIG. 3D schematically illustrates a state in which the AFS, which is a main reaction product, is sublimating.

After the COR process of the first time and the following PHT process of the first time are completed (see FIG. 3E), the COR process and the PHT process are repeatedly performed several times until the silicon oxide film 57 is completely removed. FIG. 3F schematically illustrates the COR process of the second time and FIG. 3G schematically illustrates the PHT process of the second time. In addition, FIG. 3H schematically illustrates the COR process of the third time and FIG. 3I schematically illustrates the PHT of the third time. The COR process and the PHT process may be performed four times or more, or may be finished by two times according to necessity. Here, the process conditions of the COR processes of the second and third times are the same as those of the COR process of the first time, and the process conditions of the PHT processes of the second and third times are the same as those of the PHT process of the first time, so the descriptions thereof will be omitted.

FIG. 3J schematically illustrates a state in which the silicon oxide film 57 is completely removed. The wafer W from which the silicon oxide film 57 has been completely removed through the oxide film removal process is transferred to the heat treatment device 13, and then a nitrogen gas (or an argon gas) into the chamber 22 for a predetermined time (for example, 5 seconds) in a state in which the wafer W is heated to a predetermined temperature, so that residue on the wafer W are vaporized to thereby become removed. Further, the residue removal process may be performed to follow the final PHT process in the etching device 14.

Meanwhile, in order to improve the throughput of the oxide film removal process, it is necessary to shorten the processing time of the PHT process, as well as the processing time of the COR process. Therefore, the processing time of the PHT process corresponds to the time taken for completely removing the reaction products that are produced in the COR process, and is also set as short as possible. However, the reaction products (mainly, the AFS) sublimate from the wafer W according to the following reaction formula in the PHT operation.

(NH₄)₂SiF₆(Solid)→(NH₄)₂SiF₆↑

(NH₄)₂SiF₆(Solid)→2NH₃↑+SiF₄↑+2HF↑

Thus, as shown in FIG. 4, in some cases, the gas 58 of AFS, NH₃, SiF₄, or HF (hereinafter, integrally referred to as a “sublimation gas”) that has been evaporated by sublimation stagnates in the vicinity of the wafer W in the interior of the chamber 25, thereby increasing the concentration of the sublimation gas 58. When the concentration of the sublimation gas 58 increases, the reaction from the left side to the right side of each formula above stagnates so that the sublimation of the reaction product from the wafer W becomes stagnant. As a result, a time to remove the reaction products that are produced in the COR process is required, so there is a concern of degrading the throughput of the oxide film removal. In response thereto, the present embodiment facilitates the sublimation of the reaction product from the wafer W by removing the sublimation gas 58 from the vicinity of the wafer W in the PHT process.

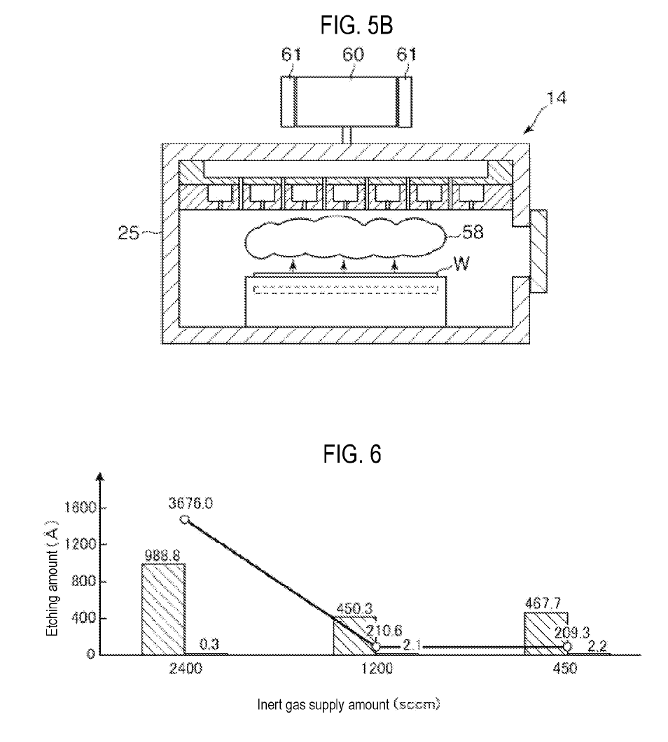

FIGS. 5A and 5B are process diagrams for explaining a removing method of the sublimation gas in the PHT process of the oxide film removal process in FIG. 3.

In the oxide film removal process of FIG. 3, an argon gas and a nitrogen gas, which are inert gases, are supplied into the chamber 25, for example, at a total flow rate of 450 sccm in the COR process, however, an inert gas is supplied into the chamber 25 at a flow rate of at least three times (for example, 1350 scccm or more) in the PHT process than that of the inert gas of the COR process. At this time, due to the increase in the amount of supplied inert gas, the internal pressure of the chamber 25 becomes higher than that of the chamber 25 of the COR process. When the amount of the supplied inert gas increases, a flow 59 of the inert gas occurs in the chamber 25 so that the sublimation gas 58 stagnating in the vicinity of the wafer W is removed from the vicinity of the wafer W (FIG. 5A). As a result, the reaction from the left side to the right side in each formula proceeds, and the sublimation of the reaction products from the wafer W is accelerated (FIG. 5B), thereby improving the throughput of the oxide film removal.

As described above, since the sublimation of the reaction product from the wafer W is accelerated in the oxide film removal process of FIGS. 3A to 3J, it is possible to shorten the processing time of the PHT process. Thus, for example, the processing time of the PHT process may be set to be 5 seconds (preferably, 3 seconds).

In addition, there is a case that the supply amount of the inert gas that increases in the PHT process may exceed the maximum supply amount of the nitrogen gas or argon gas from the nitrogen gas supply part 42 or argon gas supply part 48. In response thereto, the etching device 14 has an inert gas storage tank 60 (a gas storage unit and a gas supply unit) for additionally supplying the inert gas. The inert gas storage tank 60 pre-stores a predetermined amount of inert gas (for example, a nitrogen gas or an argon gas), and is configured to supply the stored inert gas into the chamber 25 in the PHT process. Thus, it is possible to avoid a case in which the flow 59 of the inert gas does not occur in the chamber 25 due to an insufficient supply of the inert gas in the PHT process. Here, the predetermined amount of inert gas, which is stored in the inert gas storage tank 60, is an amount that is possible to supply the inert gas at a flow rate of at least three times that of the inert gas supplied in the COR process for a predetermined period of time in the PHT process. Furthermore, the inert gas supplied from the inert gas storage tank 60 may be one of a nitrogen gas, an argon gas, or a mixed gas thereof.

Meanwhile, when an inert gas is rapidly supplied into the chamber 25 of a relatively large capacity at a high flow rate in the PHT process, there is a concern that the temperature of the supplied inert gas may decrease because of adiabatic expansion. When the temperature of the supplied inert gas is lowered, the wafer W mounted on the mounting table 26 is cooled, so that the sublimation of the reaction product is stagnated. In response thereto, the etching device 14 has a heater 61 (a gas heating unit) for heating the inert gas stored in the inert gas storage tank 60. Usually, when the temperature of the wafer W falls below 80 degrees C., the sublimation of the reaction product is extremely stagnant. Thus, the heater 61 heats the inert gas stored in the inert gas storage tank 60 such that the inert gas supplied from the inert gas storage tank 60 and expanded in the interior of the chamber 25 has a temperature of 80 degrees C. or more (preferably, 120 degrees C. or more). According to this, the lowering in the temperature of the wafer W is suppressed in the PHT process, so that the degradation of the sublimation efficiency of the reaction product from the wafer W can be prevented.

As described above, when an inert gas is supplied into the chamber 25 at a high flow rate in the PHT process, there is a concern that particles are blown away by the generated flow 59 of the inert gas and are then attached to the wafer W in the chamber 25 and, furthermore, a problem is caused due to the particles in the electronic device formed on the wafer W. In response thereto, in the oxide film removal process of FIGS. 3A to 3J, the supply amount of the inert gas in the PHT process is limited such that the difference between the internal pressure of the chamber 25 in the COR process and the internal pressure of the chamber 25 in the PHT process is less than 4 Torr. Since the particles are not blown away unless a change in the internal pressure of the chamber 25 is quite big, the configuration described above can prevent the particles from being blown away, so that it is possible to prevent the particles from being attached to the wafer W inside the chamber 25.

In addition, since the COR process and the PHT process are repeatedly performed plural times in the oxide film removal process of FIGS. 3A to 3J, it is possible to reduce the modification amount of the silicon oxide film 57 into the reaction product while the COR process is performed one time. According to this, the amount of the reaction product to be removed in the PHT process can be reduced, and the reaction product can be surely removed. As a result, it is possible to prevent the remaining reaction product from covering the silicon oxide film 57 and from hindering the reaction of the silicon oxide film 57 and the mixed gas in the subsequent COR process. Therefore, the modification efficiency into the reaction product can be maintained at a high level, thereby surely improving the throughput of the oxide film removal.

FIG. 6 is a graph showing an etching amount in the oxide film removal process of FIGS. 3A to 3J when varying the supply amount of the inert gas in the PHT process. The supply amount of the inert gas was set to have three levels (specifically, 2400 sccm, 1200 sccm, and 450 sccm). In addition, since there is a case that a silicon nitride (SiN) film is formed on the wafer W, as well as the silicon oxide film 57, and the silicon nitride also reacts with the mixed gas containing the hydrogen fluoride gas and the ammonia gas to thereby produce a reaction product in the COR process, the etching amount of the silicon nitride film, as well as the etching amount of the silicon oxide film 57, was measured. In addition, the COR process was performed for 3 seconds, and in the COR operation, an ammonia gas was supplied at a flow rate of 300 sccm, a hydrogen fluoride gas was supplied at a flow rate of 450 sccm, and an inert gas was supplied at a flow rate of 450 sccm, so that the internal pressure of the chamber 25 is maintained at 2000 mTorr. In addition, the PHT process was continued for 5 seconds, and the COR process and PHT process were repeated 50 times.

As shown in FIG. 6, the etching amount of the silicon oxide film 57 significantly increased in the case where the supply amount of the inert gas in the PHT process is at least three times (2400 sccm) than the supply amount of the inert gas in the COR process, compared with the case where the supply amount of the inert gas in the PHT process is less than three times (1200 sccm or 450 sccm) than the supply amount of the inert gas in the COR process. More specifically, the etching amount was 467.7 Å when the flow rate was 450 sccm, and the etching amount was 450.3 Å when the flow rate was 1200 sccm, whereas the etching amount was 988.8 Å when the flow rate was 2400 sccm. This is estimated because the stronger flow 59 of the inert gas occurs in the chamber 25 with an increase in the supply amount of the inert gas in the PHT process and the sublimation of the reaction product from the wafer W is accelerated, so that the remaining silicon oxide film 57 is prevented from being covered by the reaction product that cannot be completely removed, and the silicon oxide film 57 smoothly reacts with the mixed gas in the subsequent COR process so that the modification of the silicon oxide film 57 into the reaction product is not stagnant.

In addition, the etching amount of the silicon nitride film is reduced in the case where the supply amount of the inert gas in the PHT process is three times (2400 sccm) or more than the supply amount of the inert gas in the COR process, compared to the case where the supply amount of the inert gas in the PHT process is less than three times (1200 sccm or 450 sccm) than the supply amount of the inert gas in the COR process. More specifically, the etching amount was 2.2 Å when the flow rate was 450 sccm, and the etching amount was 2.1 Å when the flow rate was 1200 sccm, whereas the etching amount was 0.3 Å when the flow rate was 2400 sccm. This is estimated because the silicon oxide film 57 smoothly reacts with the mixed gas in the COR process at a flow rate of 2400 sccm so that the mixed gas to react with the silicon nitride film decreases, and as a result, the modification of the silicon nitride film into the reaction product does not proceed. In addition, the selection ratio of the silicon oxide film 57 to the silicon nitride film was 209.3 at a flow rate of 450 sccm of the inert gas in the PHT process, and the selection ratio was 210.6 at a flow rate of 1200 sccm, whereas the selection ratio was 3676.0 at a flow rate of 2400 sccm. That is, it can be seen that it is preferable to increase the supply amount of the inert gas in the PHT process so as not to positively remove the silicon nitride film in the case of using the silicon nitride film as an etching stop film.

Until now, although the embodiment of the present disclosure has been described as above, the embodiment of the present disclosure is not limited thereto.

For example, the type of a silicon oxide film to be removed in the oxide film removal process is not particularly limited, and may be a variety of silicon oxide films, such as a natural oxide film, a BPSG film, an HDP-SiO₂ film, or the like. In addition, although the nitrogen gas and the argon gas have been used as the inert gas in the PHT process of the above embodiment, one of them may be used, or other inert gases, such as a helium gas or a xenon gas, or a mixture thereof may be used.

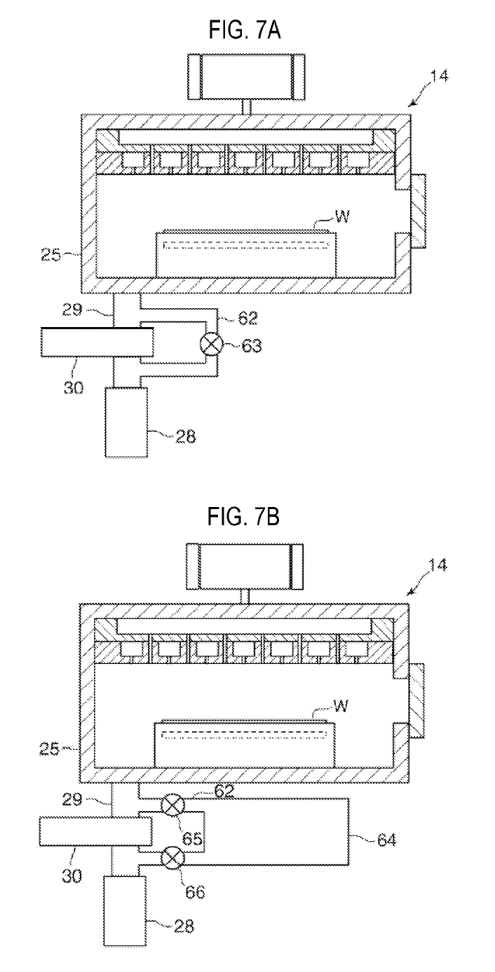

Furthermore, when an inert gas is supplied into the chamber 25 at a high flow rate in the PHT process, since the opening area of the APC valve 30 is limited, the conductance of the exhaust gas may be reduced and the sublimation gas 58 may stagnate in the interior of the chamber 25 so that there is a concern that the occurrence of the inert gas flow 59 may be difficult. In response thereto, as shown in FIG. 7A, a bypass line 62 is installed to connect the exhaust duct 29 to the TMP 28 by detouring the APC valve 30 in the exhaust unit of the etching device 14, and a bypass valve 63 is installed on the bypass line 62 for opening or closing thereof. At this time, the bypass line 62 is opened by means of the bypass valve 63 in the PHT process to allow the exhaust gas to flow from the chamber 25 to the TMP 28 through the bypass line 62, as well as through the APC valve 30. According to this, it is possible to improve the conductance of the exhaust gas and to prevent the sublimation gas 58 from stagnating in the interior of the chamber 25, so that it ensures the occurrence of the inert gas flow 59 in the chamber 25.

In addition, a buffer tank 64 is installed on the bypass line 62, and a tank valve 65 is installed to separate the exhaust duct 29 and the buffer tank 64 from each other, or a tank valve 66 is installed to separate the buffer tank 64 and the TMP 28 from each other. At this time, the tank valve 65 is opened to communicate the exhaust duct 29 with the buffer tank 64 in the PHT process so that the exhaust gas containing the sublimation gas 58 that has failed to completely pass through the APC valve 30 is introduced and stored into the buffer tank 64. Thus, it is possible to prevent the sublimation gas 58 from stagnating in the interior of the chamber 25. Further, in the subsequent COR process, the tank valve 66 is opened to communicate the buffer tank 64 with the TMP 28, so that the exhaust gas stored in the buffer tank 64 is exhausted by means of the TMP 28.

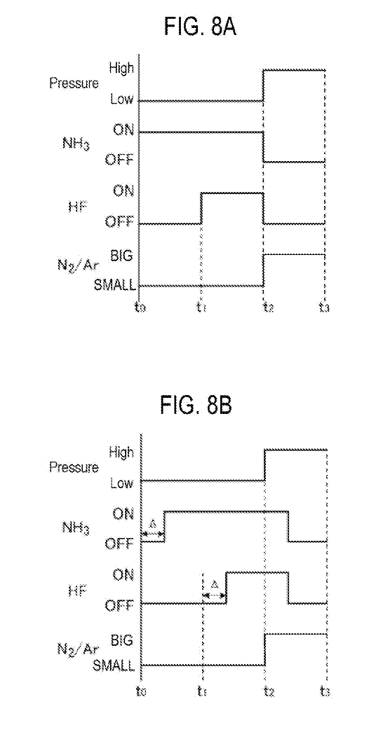

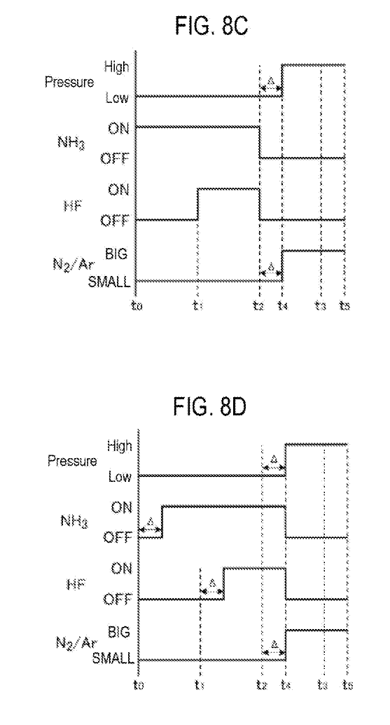

A supply timing of an ammonia gas, a hydrogen fluoride gas, or an inert gas (argon gas or nitrogen gas) may be more finely controlled in the COR process. FIG. 8A is a timing chart showing a supply start or supply stop of various gases in the COR process and the PHT process. In addition, for each of the ammonia gas and the hydrogen fluoride gas, “ON” indicates that a gas is supplied and “OFF” indicates that the supply of gas is stopped. Further, the supply of the inert gas does not stop in the course of the process, and “BIG” represents that a supply amount of the inert gas is big and “SMALL” represents that a supply amount of the inert gas is small.

In the timing chart of FIG. 8A, the COR process is initiated at time t0 so that an ammonia gas and an inert gas are supplied into the chamber 25. In addition, a hydrogen fluoride gas is supplied into the chamber 25 at time t1. At the following time t2, in order to switch from the COR process to the PHT process, the supply amount of the inert gas increases while the supply of the hydrogen fluoride gas and the ammonia gas is stopped to increase the internal pressure of the chamber 25. Thereafter, the PHT process is terminated at time t3.

FIG. 8B is a chart showing an actual change in the internal pressure of the chamber 25 and the supply/stop state of gases when the timing chart of FIG. 8A is implemented. As described with reference to FIG. 2, the ammonia gas valve 40 is installed on the ammonia gas supply pipe 39 that connects the ammonia gas supply part 41 and the chamber 25, and a specific pipe length of the ammonia gas supply pipe 39 exits from the ammonia gas valve 40 to the chamber 25. Likewise, the hydrogen fluoride gas valve 46 is installed on the hydrogen fluoride gas supply pipe 45 that connects the hydrogen fluoride gas supply part 47 and the chamber 25, and a specific pipe length of the hydrogen fluoride gas supply pipe 45 exists from the hydrogen fluoride gas valve 46 to the chamber 25.

Therefore, even if the ammonia gas valve 40 and the hydrogen fluoride gas valve 46 are opened at time t0 and time t1, respectively, as shown in FIG. 8B, there is a delay time A for the ammonia gas and the hydrogen fluoride gas to actually reach the interior of the chamber 25. Here, for the sake of simple explanation, it is assumed that the ammonia gas and the hydrogen fluoride gas have the same delay time A. Further, even when the ammonia gas valve 40 and the hydrogen fluoride gas valve 46 are closed at time t2 in order to stop the supply of the ammonia gas and hydrogen fluoride gas, the ammonia gas and hydrogen fluoride gas are continuously supplied into the chamber 25 for a while.

Here, in the oxide film removal process of FIG. 3, since the processing time of the COR process of one time is short (3 seconds), when the supply amount of the inert gas increases before a predetermined amount of hydrogen fluoride gas is supplied into the chamber 25, a portion of the hydrogen fluoride gas does not participate in the reaction with the silicon oxide film 57 and is removed from the vicinity of the wafer W and the distribution uniformity of the hydrogen fluoride gas is degraded in the chamber 25 by the inert gas flow 59 occurring due to the increase in the supply amount of the inert gas. As a result, there are concerns that the modification amount of the silicon oxide film 57 into the reaction product is reduced, and the in-plane uniformity with respect to the generation of the reaction product is degraded. In addition, since the supply time of the ammonia gas is longer than the supply time of the hydrogen fluoride gas, the delay of the ammonia gas supply does not really matter.

Accordingly, the timing of stopping the supply of the hydrogen fluoride gas into the chamber 25 may be adjusted to the timing of increasing the amount of supplied inert gas at a time of transition from the COR process to the PHT process by adjusting the timing of increasing the supply amount of the inert gas according to the supply delay caused by the length of the hydrogen fluoride gas supply pipe 45.

FIG. 8C is a timing chart of a modified example of the oxide film removal process. In the timing chart of the ammonia gas, the hydrogen fluoride gas, and the inert gas shown in FIG. 8C, the supply amount of the inert gas increases at time t4, which is later than time t2 by a time A. In addition, the end timing of the PHT process is prolonged from time t3 to time t5, which is later by a time A, to secure the processing time of the PHT process. Here, the time A is dependent on the length of the hydrogen fluoride gas supply pipe 45 from the hydrogen fluoride gas valve 46 to the chamber 25, and may be approximately 1 second to 3 seconds (preferably, 2 seconds). Meanwhile, it is not preferable to set a long time because the throughput is lowered.

FIG. 8D is a chart showing an actual change in the internal pressure of the chamber 25 and the supply/stop state of gases when the timing chart of FIG. 8C is implemented. As shown in FIG. 8D, the timing of stopping the supply of the hydrogen fluoride gas into the chamber 25 matches the timing of increasing the amount of supplied inert gas by increasing the amount of supplied inert gas at time t4, which is later than time t2 by a time A. According to this, since the inert gas flow 59 occurs after a predetermined amount of hydrogen fluoride gas completely reacts with the silicon oxide film 57, it is possible to eliminate the problem in which a portion of the hydrogen fluoride gas does not react with the silicon oxide film 57 and is not removed from the vicinity of the wafer W, and the distribution uniformity of the hydrogen fluoride gas is prevented from being degraded in the chamber 25. As a result, a predetermined amount of silicon oxide film 57 can be surely modified into the reaction product, and the in-plane uniformity with respect to the generation of the reaction product can be improved.

In addition, the present disclosure may be achieved by supplying a storage unit 54 in which a program code of software for executing the functions of the embodiment described above is recorded to the process controller 52 provided in the control unit 15 and by reading and executing the program code stored in the storage unit 54 by a CPU of the process controller 52.

In this case, the program code itself that is read out from the storage unit 54 implements the functions of the embodiment described above, and the program code and the storage unit 54 storing the same constitute the present disclosure.

Further, the storage unit 54, for example, may be RAM, NV-RAM, a floppy (registered trademark) disc, a hard disc, a magneto-optical disc, an optical disc, such as CD-ROM, CD-R, CD-RW, or DVD (DVD-ROM, DVD-RAM, DVD-RW, DVD+RW), a magnetic tape, a non-volatile memory card, or other ROMs that can memorize the program code. Furthermore, the program code may be downloaded from a computer or database (not shown) that is connected to the Internet, a commercial network, or a local area network to then be provided to the process controller 52.

In addition, the process controller 52 may execute the read program code to implement the functions of the embodiment above, or an OS (Operating System) that is operated in the CPU may execute all or some of the actual processes based on instructions of the program code to implement the functions of the embodiment above.

Furthermore, the program code read out from the storage unit 54 may be written in the memory provided in the function extension board that is inserted into the process controller 52 or in the function extension unit that is connected to the process controller 52, and a CPU provided in the function extension board or function extension unit may execute all or some of the actual processes based on instructions of the program code to implement the functions of the embodiment above.

The program code may be configured in the form of an object code, a program code executed by an interpreter, script data supplied to the OS, or the like.

According to the present disclosure, since the internal pressure of the processing chamber in the sublimation process becomes higher than the internal pressure of the processing chamber in the reaction operation by supplying an inert gas into the processing chamber, an inert gas flow occurs in the interior of the processing chamber in the sublimation process so that the reaction product gas that sublimates from the substrate can be removed from the vicinity of the substrate by means of the inert gas flow. As a result, the sublimation of the reaction product from the substrate is accelerated, thereby improving the throughput of the oxide film removal.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

1-12. (canceled)

13. A substrate processing apparatus comprising:
a processing chamber configured to accommodate a substrate;
a gas supply unit configured to selectively supply a halogen element-containing gas, an alkaline gas, or an inert gas into the processing chamber; and
a temperature controller configured to adjust a temperature of the substrate accommodated in the processing chamber,
wherein the gas supply unit is configured to perform modifying an oxide film formed on the substrate accommodated in the processing chamber into a reaction product by supplying the halogen element-containing gas and the alkaline gas into the processing chamber, and perform sublimating the reaction product for removal from the substrate by stopping the supply of the halogen element-containing gas into the processing chamber,
wherein the gas supply unit is configured to supply an inert gas into the processing chamber to set an internal pressure of the processing chamber in the sublimating to be higher than an internal pressure of the processing chamber in the modifying, and
wherein the temperature controller is configured to maintain the temperature of the substrate at a predetermined temperature in the modifying, and maintain the temperature of the substrate at the predetermined temperature in the sublimating.

14. The substrate processing apparatus of claim 13, wherein the gas supply unit is configured to set a supply amount of the inert gas into the processing chamber in the sublimating to be more than a supply amount of the inert gas into the processing chamber in the modifying.

15. The substrate processing apparatus of claim 14, wherein the gas supply unit is configured to set the supply amount of the inert gas into the processing chamber in the sublimating to be at least three times the supply amount of the inert gas into the processing chamber in the modifying.

16. The substrate processing apparatus of claim 13, wherein the gas supply unit is configured to repeatedly perform the sublimating and the modifying plural times.

17. The substrate processing apparatus of claim 13, further comprising a gas heating unit configured to heat the inert gas,
wherein the gas heating unit is configured to maintain a temperature of the inert gas supplied into the processing chamber in the sublimating to be 80 degrees C. or more.

18. The substrate processing apparatus of claim 17, wherein the gas heating unit is configured to maintain the temperature of the inert gas supplied into the processing chamber in the sublimating to be 120 degrees C. or more.

19. The substrate processing apparatus of claim 13, wherein the gas supply unit is configured to set a difference between the internal pressure of the processing chamber in the sublimating and the internal pressure of the processing chamber in the modifying to be less than 4 Torr.

20. The substrate processing apparatus of claim 13, further comprising a gas storage unit configured to pre-store the inert gas,
wherein the gas storage unit is configured to supply the pre-stored inert gas into the processing chamber in the sublimating.
